(19) United States
(12) Patent Application Publication
(10) Pub. No.: US 2025/0275178 A1
(43) Pub. Date: Aug. 28, 2025

(54) SEMICONDUCTOR DEVICE

(71) Applicant: Hon Young Semiconductor Corporation, Hsinchu City (TW)

(72) Inventor: Yan-Ru CHEN, Hsinchu City (TW)

(21) Appl. No.: 18/638,697

(22) Filed: Apr. 18, 2024

(30) Foreign Application Priority Data
Feb. 23, 2024 (TW) 113106518

(51) Int. Cl. H01L 29/78; H01L 29/06; H01L 29/08; H01L 29/417

(52) U.S. Cl. CPC H10D 30/668; H10D 62/127; H10D 62/154; H10D 64/252

(57) ABSTRACT

A semiconductor device includes a substrate, a source trench structure, a gate trench structure and a drain electrode. The source trench structure is in the substrate. The gate trench structure is in the substrate, and a bottom of the gate trench structure is higher than a bottom of the source trench structure. The gate trench structure surrounds the source trench structure and defines a device unit, and a first projection area of the source trench structure along a fixed direction is less than 20% of a second projection area of the device unit along the fixed direction. The drain electrode is below the substrate.

### CROSS-REFERENCE TO RELATED APPLICATION

This application claims priority to Taiwan Application Serial Number 113106518 filed Feb. 23, 2024, which is herein incorporated by reference.

### BACKGROUND

### Technical Field

Some embodiments of the present disclosure relate to a semiconductor device.

### Description of Related Art

Metal oxide semiconductor field effect transistors (MOSFETs) can be classified into horizontal-channel MOSFETs and vertical-channel MOSFETs according to the channel direction thereof. The vertical-channel MOSFETs can provide the same current with a relatively small area while obtaining a relatively low on-resistance, thereby remarkably reducing the production cost. Thus, further improving the efficacy of vertical-channel MOSFETs has also become one of important issues.

### SUMMARY

Some embodiments of the present disclosure provide a semiconductor device, including a substrate, a source trench structure, a gate trench structure and a drain electrode. The source trench structure is in the substrate. The gate trench structure is in the substrate, a bottom of the gate trench structure being higher than a bottom of the source trench structure, where the gate trench structure surrounds the source trench structure and defines a device unit, and a first projection area of the source trench structure along a fixed direction is less than 20% of a second projection area of the device unit along the fixed direction. The drain electrode is below the substrate.

In some embodiments, the first projection area of the source trench structure is less than 15% of the second projection area of the device unit.

In some embodiments, the first projection area of the source trench structure is more than 5% of the second projection area of the device unit.

In some embodiments, the device unit has a shape of hexagon, quadrangle or triangle in a top view.

In some embodiments, the device unit has a shape of hexagon in a top view, and the hexagon has a first side and a second side, where the first side has a greater length than the second side.

In some embodiments, four sides of the hexagon have a first length, and the remaining two sides have a second length different from the first length.

In some embodiments, the substrate further includes a source doped region, between the gate trench structure and the source trench structure.

In some embodiments, a source contact extends from an upper surface of the source doped region to an upper surface of the source trench structure.

In some embodiments, the source trench structure includes a dielectric layer and a conductor layer, and the conductor layer is surrounded by the dielectric layer.

In some embodiments, the gate trench structure includes a gate dielectric layer and a gate layer, and the gate layer is surrounded by the gate dielectric layer.

Some embodiments of the present disclosure provide a semiconductor device, including a substrate, a source trench structure, a gate trench structure and a drain electrode. The substrate includes a source region. The source trench structure is in the substrate. The gate trench structure is in the substrate and adjacent to the source region, a bottom of the gate trench structure being higher than a bottom of the source trench structure, where the gate trench structure surrounds the source trench structure and defines a device unit, and an interface between the gate trench structure and the source region of the substrate along a fixed direction is a hexagon. The drain electrode is below the substrate.

In some embodiments, the source region is between the gate trench structure and the source trench structure.

In some embodiments, the six sides of the hexagon have substantively the same length.

In some embodiments, the hexagon has a first side and a second side, where the first side has a greater length than the second side.

In some embodiments, the first projection area of the source trench structure along a fixed direction is 5% to 20% of the second projection area of the device unit along the fixed direction.

In some embodiments, the first projection area of the source trench structure is 5% to 15% of the second projection area of the device unit along a fixed direction.

In some embodiments, four sides of the hexagon have a first length, and the remaining two sides have a second length different from the first length.

In some embodiments, the source region is a source doped region, between the gate trench structure and the source trench structure.

In some embodiments, the source trench structure includes a dielectric layer and a conductor layer, and the conductor layer is surrounded by the dielectric layer.

In some embodiments, the gate trench structure includes a gate dielectric layer and a gate layer, and the gate layer is surrounded by the gate dielectric layer.

### BRIEF DESCRIPTION OF THE DRAWINGS

FIG. 1 is a top view of a semiconductor device according to some embodiments of the present disclosure.

FIG. 2 is a cross-sectional view along a line A-A′ of FIG. 1.

FIG. 3 is a top view of a semiconductor device according to some other embodiments of the present disclosure.

FIG. 4 is a top view of a semiconductor device according to some other embodiments of the present disclosure.

FIG. 5 is a top view of a semiconductor device according to some other embodiments of the present disclosure.

### DETAILED DESCRIPTION

Some embodiments of the present disclosure relate to a double-trench semiconductor device, for example, a double-trench metal-oxide-semiconductor field-effect transistor (MOSFET). The double-trench semiconductor device may include a source trench structure and a gate trench structure, and the source trench structure can be used to protect the corner of the gate trench structure to avoid problems concerning the reliability of the gate trench structure. In the present disclosure, the top view area of the source trench structure can be controlled at a proper size so that the on-resistance of the semiconductor device can be maintained low while the source trench structure still has ability of protecting the corner of the gate trench structure.

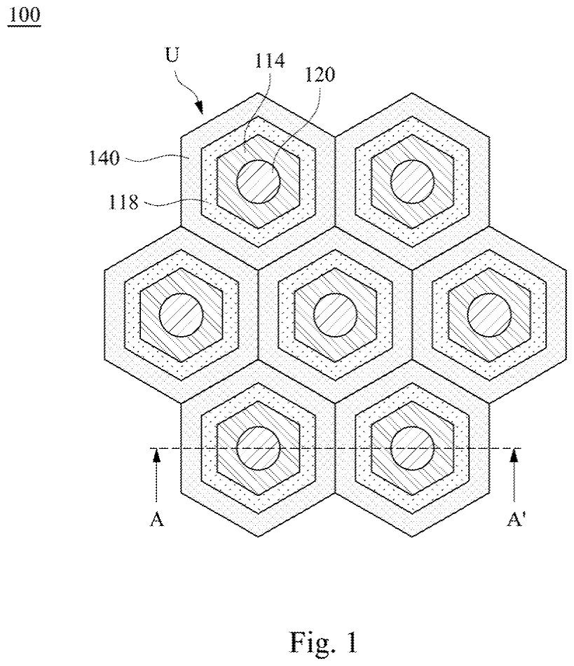

FIG. 1 is a top view of a semiconductor device 100 according to some embodiments of the present disclosure. Referring to FIG. 1, the semiconductor device 100 includes a plurality of device units U, and the device units U can be closely arranged together. For instance, all boundaries of one of the device units U contact the boundaries of other device units U. In some embodiments, in the top view, the device unit U has a shape of hexagon in the top view, as shown in FIG. 1. It should be noted that, for simplicity of illustration, FIG. 1 only depicts some of the components.

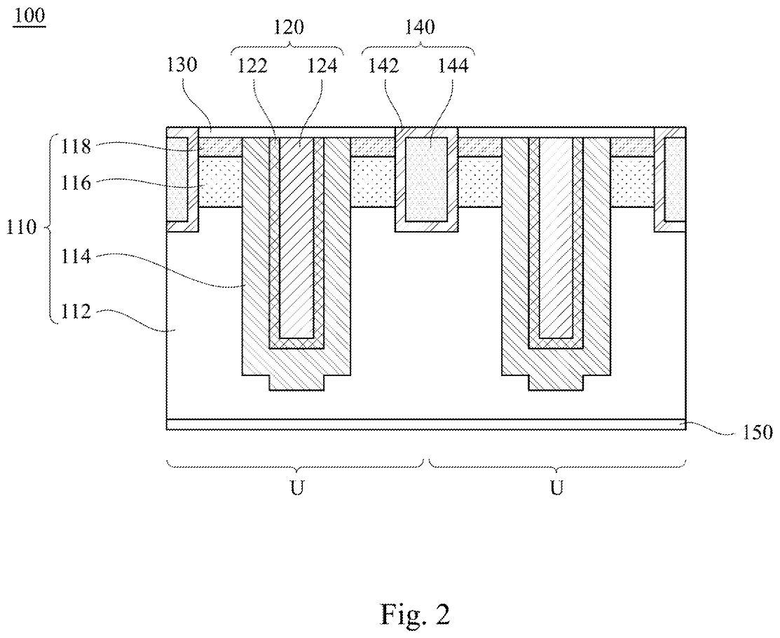

FIG. 2 is a cross-sectional view along a line A-A′ of FIG. 1. Referring to FIG.

2, the semiconductor device 100 may include a substrate 110, a source trench structure 120, a source contact 130, a gate trench structure 140 and a drain electrode 150.

The substrate 110 includes a drift region 112, a body contact region 114, a well region 116 and a source region 118 (also referred to as a source doped region 118). The body contact region 114, the well region 116 and the source region 118 are on the drift region 112. The body contact region 114 extends downward from an upper surface of the substrate 110. The well region 116 transversely surrounds the body contact region 114. The source region 118 transversely surrounds the body contact region 114 and is on the well region 116. In some embodiments, the drift region 112 and the source region 118 have a first conductivity type, the well region 116 and the body contact region 114 have a second conductivity type, and the first conductivity type is different from the second conductivity type. In some embodiments, the source region 118 is an N-type heavily-doped region, the drift region 112 is an N-type lightly-doped region, the well region 116 is a P-type lightly-doped region or moderately-doped region, and the body contact region 114 is a P-type heavily-doped region. In some embodiments, the substrate 110 is made from silicon or silicon carbide.

The source trench structure 120 is in the substrate 110, and is surrounded by the body contact region 114. In some embodiments, an interface between the source trench structure 120 and the body contact region 114 is a circular outline. The source trench structure 120 includes a dielectric layer 122 and a semiconductor layer (or a conductor layer) 124. The semiconductor layer 124 is surrounded by the dielectric layer 122, and the dielectric layer 122 is surrounded by the body contact region 114. In other words, the dielectric layer 122 is between the body contact region 114 and the semiconductor layer 124. In some embodiments, the dielectric layer 122 can be made from silicon oxide, silicon nitride or other analogues. In some embodiments, the semiconductor layer 124 is made from polycrystalline silicon. The source contact 130 is on the source trench structure 120, and further extends from an upper surface of the source region 118 to an upper surface of the source trench structure 120. In some embodiments, the source contact 130 can be made from a metal.

The gate trench structure 140 is in the substrate 110, and surrounds the source trench structure 120, the well region 116 and the source region 118. Therefore, the source region 118 is between the source trench structure 120 and the gate trench structure 140. The gate trench structure 140 includes a gate dielectric layer 142 and a gate layer 144. The gate layer 144 is surrounded by the gate dielectric layer 142, and the gate dielectric layer 142 contacts the well region 116 and the source region 118. In other words, the well region 116 and the source region 118 are between the source trench structure 120 and the gate trench structure 140. A bottom of the gate trench structure 140 is higher than a bottom of the source trench structure 120. In some embodiments, the gate dielectric layer 142 can be made from silicon oxide, silicon nitride or other analogues. In some embodiments, the gate layer 144 is made from a semiconductor or conductor, for example, polycrystalline silicon. In some embodiments, an interface between the well region 116 and the gate trench structure 140 is a hexagon. In some embodiments, an interface between the source region 118 and the gate trench structure 140 has a different shape from an interface between the source trench structure 120 and the body contact region 114.

The drain electrode 150 is below the substrate 110. In some embodiments, the substrate 110 can be otherwise formed on a heavily-doped substrate having a first conductivity type. Therefore, the drain electrode 150 and the substrate 110 can be formed at two opposite sides of the heavily-doped substrate having the first conductivity type. In some embodiments, the drain electrode 150 can be made from a metal.

The semiconductor device 100 of the present disclosure is a vertical-channel device, which can increase the current on a unit area. Specifically, the semiconductor device of the present disclosure consists of a plurality of device units U, and in the top view (FIG. 1, for instance), the gate trench structure 140 defines a device unit U. It should be noted that, although there is a distinct boundary between the device units U in FIG. 1, it is merely intended for clearly showing the range of each device unit U. In fact, there is no distinct boundary between the device units U. For example, adjacent device units U can share a gate trench structure 140. Thus, the top view area of each of the device units U can be defined as an area enclosed by a line connecting the midpoints of the gate trench structure 140. When the semiconductor device 100 is in operation, in each of the device units U, an electron flow can flow downward to the drift region 112 from the source contact 130 along the source region 118 and the well region 116 on a side wall of the gate trench structure 140, and then flow to the drain electrode 150. Now, a high electric field of the drain electrode 150 may induce a problem concerning reliability of the gate dielectric layer 142 at the corner of the gate trench structure 140.

The source trench structure 120 and the body contact region 114 around the source trench structure 120 can be used to protect the corner region of the gate trench structure 140. Specifically, when the semiconductor device 100 is in operation, the source trench structure 120 is electrically connected to the source contact 130, the body contact region 114 around the source trench structure 120 has a second conductivity type while the drift region 112 has a first conductivity type, and a depletion region is formed between the body contact region 114 and the drift region 112 to protect the corner region of the gate trench structure 140. Therefore, the impact of the high electric field of the drain electrode 150 on the corner region of the gate trench structure 140 can be diminished. Since the source trench structure 120 per se cannot provide current, controlling the dimensions of the source trench structure 120 within an appropriate range can properly protect the corner region of the gate trench structure 140 while the dimensions of the semiconductor device 100 are reduced. In some embodiments, the first projection area of the source trench structure 120 along a fixed direction is less than 20% of the second projection area of the device unit U along the fixed direction (FIG. 1). In some embodiments, the first projection area of the source trench structure 120 is more than 5% of the second projection area of the device unit U (FIG. 1). When the proportion of the first projection area of the source trench structure 120 is beyond the above-mentioned range, the source trench structure 120 may occupy a larger part, making it impossible to reduce the dimensions of the semiconductor device 100 and hence the on-resistance of the semiconductor device 100. When the proportion of the first projection area of the source trench structure 120 is below the above-mentioned range, the source trench structure 120 may be too far from the gate trench structure 140, and thus the depletion region formed by the body contact region 114 and the drift region 112 around the source trench structure 120 cannot effectively protect the corner region of the gate trench structure 140. In some embodiments, the first projection area of the source trench structure 120 along a fixed direction and the second projection area of the device unit U along the fixed direction are shown in FIG. 1.

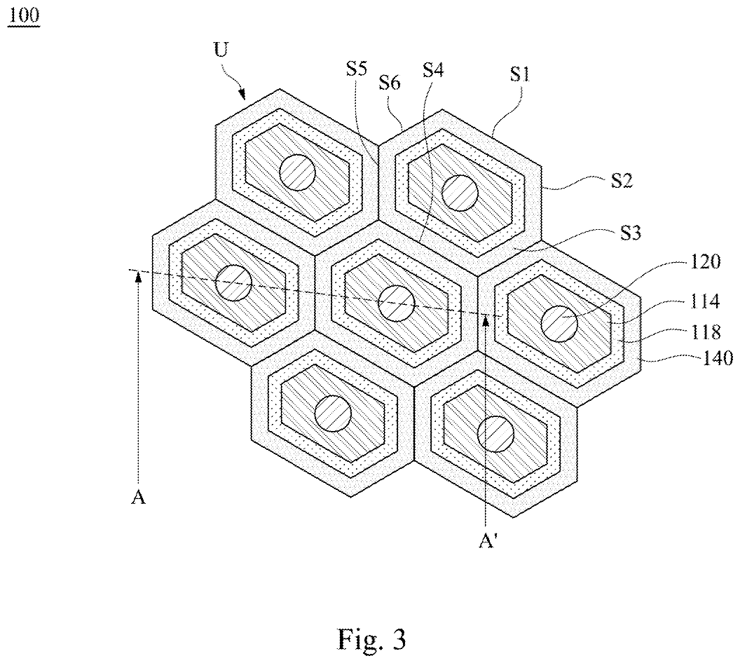

FIG. 3 is a top view of a semiconductor device 100 according to some other embodiments of the present disclosure. A cross-sectional view along a line A-A′ of FIG. 3 can also be shown in FIG. 2. The semiconductor device 100 of FIG. 3 is similar to the semiconductor device 100 of FIG. 1, with a difference in that the six sides of the hexagon of the device unit U of the semiconductor device 100 of FIG. 1 have substantively the same length. On the other hand, the device unit U of the semiconductor device 100 of FIG. 3 has a first side S1, a second side S2, a third side S3, a fourth side S4, a fifth side S5 and a sixth side S6 connected clockwise, where four sides of the hexagon (for example, the second side S2, the third side S3, the fifth side S5 and the sixth side S6) have substantively the same first length, and the remaining two sides (for example, the first side S1 and the fourth side S4) of the hexagon have a second length different from the first length. In some embodiments, the length of the first side S1 and the fourth side S4 is greater than the length of the second side S2, the third side S3, the fifth side S5 and the sixth side S6. When the top view of the semiconductor device 100 is shown in FIG. 3, the proportion of the top view area of the source trench structure 120 based on the top view area of the device unit U can be further reduced relative to FIG. 1. For example, the first projection area of the source trench structure 120 is less than 15% of the second projection area of the device unit U, but such proportion can still be more than 5%. Therefore, the source trench structure 120 can properly protect the corner region of the gate trench structure 140 while the dimensions of the semiconductor device 100 are reduced.

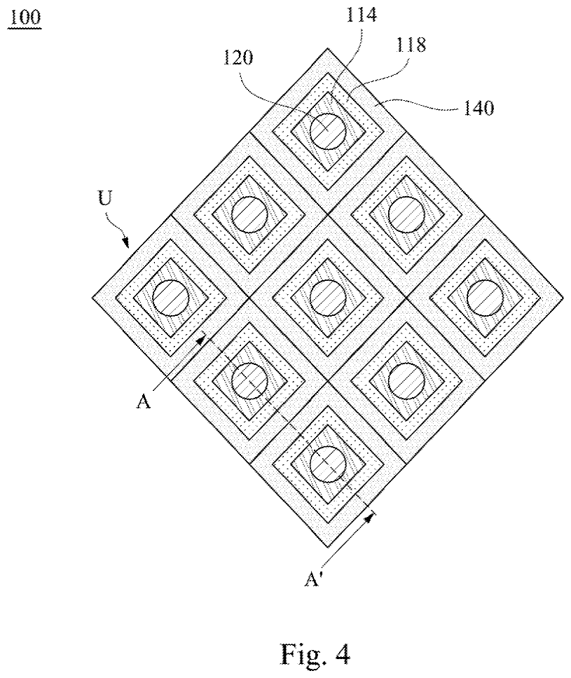

FIG. 4 is a top view of a semiconductor device 100 according to some other embodiments of the present disclosure. A cross-sectional view along a line A-A′ of FIG. 4 can also be shown in FIG. 2. The semiconductor device 100 of FIG. 4 is similar to the semiconductor device 100 of FIG. 1, with a difference in that the device unit U of the semiconductor device 100 of FIG. 4 has a shape of rhombus in the top view. In some embodiments, an interface between the source region 118 and the gate trench structure 140 is also a rhombus. When the device unit U has a shape of rhombus in the top view, the on-resistance of the semiconductor device will be further reduced.

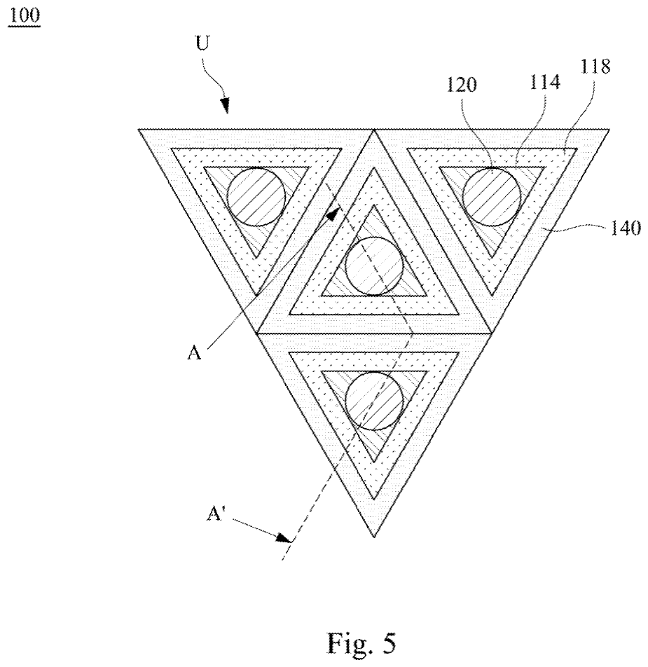

FIG. 5 is a top view of a semiconductor device 100 according to some other embodiments of the present disclosure. A cross-sectional view along a line A-A′ of FIG. 5 can also be shown in FIG. 2. The semiconductor device 100 of FIG. 5 is similar to the semiconductor device 100 of FIG. 1, with a difference in that the device unit U of the semiconductor device 100 of FIG. 5 has a shape of triangle in the top view. In some embodiments, an interface between the source region 118 and the gate trench structure 140 is also a triangle. When the device unit U has a shape of triangle in the top view, the on resistance of the semiconductor device will be further reduced.

It should be noted that, although some embodiments of the present disclosure provide device units U having different top-view shapes, the present disclosure is not limited thereto. As long as the proportion of the first protection area of the source trench structure 120 in the semiconductor device 100 based on the second projection area of the device unit U is within the scope of protection of the present disclosure, it can fall within the scope of protection of the present disclosure. In some embodiments of the present disclosure, the first projection area of the source trench structure 120 is less than 20% and more than 5% of the second projection area of the device unit U. Therefore, the source trench structure 120 can properly protect the corner region of the gate trench structure 140 while the dimensions of the semiconductor device 100 are reduced.

What is claimed is:

1. A semiconductor device, comprising:
a substrate;
a source trench structure, in the substrate;
a gate trench structure, in the substrate, a bottom of the gate trench structure being higher than a bottom of the source trench structure, wherein the gate trench structure surrounds the source trench structure and defines a device unit, wherein a first projection area of the source trench structure along a fixed direction is less than 20% of a second projection area of the gate trench structure along the fixed direction; and
a drain electrode, below the substrate.

2. The semiconductor device of claim 1, wherein the first projection area of the source trench structure is less than 15% of the second projection area of the device unit.

3. The semiconductor device of claim 1, wherein the first projection area of the source trench structure is more than 5% of the second projection area of the device unit.

4. The semiconductor device of claim 1, wherein the device unit has a shape of hexagon, quadrangle or triangle in a top view.

5. The semiconductor device of claim 1, wherein the device unit has a shape of hexagon in a top view, and the hexagon has a first side and a second side, wherein the first side has a greater length than the second side.

6. The semiconductor device of claim 5, wherein four sides of the hexagon have a first length, and the remaining two sides have a second length different from the first length.

7. The semiconductor device of claim 1, wherein the substrate further comprises:
a source doped region, between the gate trench structure and the source trench structure.

8. The semiconductor device of claim 7, further comprising:
a source contact extending from an upper surface of the source doped region to an upper surface of the source trench structure.

9. The semiconductor device of claim 1, wherein the source trench structure comprises:
a dielectric layer; and
a conductor layer, surrounded by the dielectric layer.

10. The semiconductor device of claim 1, wherein the gate trench structure comprises:
a gate dielectric layer; and
a gate layer, surrounded by the gate dielectric layer.

11. A semiconductor device, comprising:
a substrate, comprising a source region;
a source trench structure, in the substrate;
a gate trench structure, in the substrate and adjacent to the source region, a bottom of the gate trench structure being higher than a bottom of the source trench structure, wherein the gate trench structure surrounds the source trench structure and defines a device unit, and an interface between the gate trench structure and the source region of the substrate along a fixed direction is a hexagon; and
a drain electrode, below the substrate.

12. The semiconductor device of claim 11, wherein the source region is between the gate trench structure and the source trench structure.

13. The semiconductor device of claim 12, further comprising:
a source contact extending from an upper surface of the source region to an upper surface of the source trench structure.

14. The semiconductor device of claim 11, wherein six sides of the hexagon have substantively the same length.

15. The semiconductor device of claim 11, wherein the hexagon has a first side and a second side, and the first side has a greater length than the second side.

16. The semiconductor device of claim 11, wherein a first projection area of the source trench structure along the fixed direction is 5% to 20% of a second projection area of the device unit along the fixed direction.

17. The semiconductor device of claim 11, wherein in a top view, a first projection area of the source trench structure along the fixed direction is 5% to 15% of a second projection area of the device unit along the fixed direction.

18. The semiconductor device of claim 11, wherein four sides of the hexagon have a first length, and the remaining two sides have a second length different from the first length.

19. The semiconductor device of claim 11, wherein the source trench structure comprises:
a dielectric layer; and
a conductor layer, surrounded by the dielectric layer.

20. The semiconductor device of claim 11, wherein the gate trench structure comprises:
a gate dielectric layer; and
a gate layer, surrounded by the gate dielectric layer.
